(19) United States
(12) Patent Application Publication
(10) Pub. No.: US 2025/0191987 A1
(43) Pub. Date: Jun. 12, 2025

(54) SEMICONDUCTOR DEVICE

(71) Applicant: SHINKO ELECTRIC INDUSTRIES CO., LTD., Nagano-shi (JP)

(72) Inventor: Shinichiro SEKIJIMA, Nagano-shi (JP)

(21) Appl. No.: 18/973,394

(22) Filed: Dec. 9, 2024

(30) Foreign Application Priority Data
Dec. 12, 2023 (JP) 2023-209452

(51) Int. Cl. H01L 23/31; H01L 23/373

(52) U.S. Cl. CPC H01L 23/3107; H01L 23/3736

(57) ABSTRACT

A semiconductor device includes a wiring substrate, a semiconductor element mounted on the wiring substrate, and a heat dissipation plate arranged above the semiconductor element. The semiconductor device further includes an encapsulation resin that encapsulates the semiconductor element and fills a gap between the wiring substrate and the heat dissipation plate. The heat dissipation plate includes a main body that overlaps the semiconductor element in plan view, and a lead that projects outward from the main body. The lead is thinner than the main body. The encapsulation resin includes an upper surface located downward from an upper surface of the main body. The encapsulation resin covers an upper surface of the lead and part of a side surface of the main body. The encapsulation resin exposes an entirety of the upper surface of the main body and an upper portion of the side surface of the main body.

### CROSS-REFERENCE TO RELATED APPLICATIONS

This application is based upon and claims the benefit of priority from Japanese Patent Application No. 2023-209452, filed on Dec. 12, 2023, the entire contents of which are incorporated herein by reference.

### BACKGROUND

### 1. Field

The following description relates to a semiconductor device and a method for manufacturing a semiconductor device.

### 2. Description of Related Art

A typical semiconductor device includes a wiring substrate, a semiconductor element mounted on the wiring substrate, a lead frame mounted on the wiring substrate with connecting members, and an encapsulation resin encapsulating the semiconductor element and the connecting members. Japanese Laid-Open Patent Publication No. 2021-072434 discloses an example of such a semiconductor device. In this type of semiconductor device, a lower surface of the lead frame is flush with a lower surface of the encapsulation resin. In the semiconductor device, the lower surface of the lead frame exposed from the encapsulation resin may be used as a recognition mark, such as an alignment mark.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In the above semiconductor device, there is a demand for improvement in visual recognition of the recognition mark.

In one general aspect, a semiconductor device includes a wiring substrate, a semiconductor element mounted on the wiring substrate, a heat dissipation plate arranged above the semiconductor element, and an encapsulation resin encapsulating the semiconductor element and filling a gap between the wiring substrate and the heat dissipation plate. The heat dissipation plate includes a main body overlapping the semiconductor element in plan view, and a lead projecting outward from the main body. The lead is thinner than the main body. The encapsulation resin includes a first outer side surface. The lead includes a second outer side surface exposed from the first outer side surface of the encapsulation resin. The encapsulation resin covers an upper surface of the lead and part of a side surface of the main body. The encapsulation resin includes an upper surface located downward from an upper surface of the main body. The encapsulation resin exposes an entirety of the upper surface of the main body and an upper portion of the side surface of the main body.

Other features and aspects will be apparent from the following detailed description, the drawings, and the claims.

### BRIEF DESCRIPTION OF THE DRAWINGS

FIG. 1A is a schematic cross-sectional view of a semiconductor device in accordance with an embodiment (cross-sectional view taken along line 1-1 in FIG. 2).

FIG. 1B is a partially enlarged cross-sectional view of the semiconductor device illustrated in FIG. 1A.

FIG. 2 is a schematic plan view of the semiconductor device illustrated in FIG. 1A.

FIG. 3 is a cross-sectional view of the semiconductor device taken along line 3-3 in FIG. 2.

FIG. 4 is a schematic side view of the semiconductor device.

FIG. 5 is a schematic plan view illustrating a method for manufacturing the semiconductor device in accordance with the embodiment.

FIG. 6 is a cross-sectional view taken along line 6-6 in FIG. 5.

FIG. 7 is a schematic cross-sectional view illustrating the method for manufacturing the semiconductor device.

FIG. 8 is a schematic plan view illustrating the method for manufacturing the semiconductor device.

FIG. 9 is a cross-sectional view taken along line 9-9 in FIG. 8.

FIGS. 10, 11, 12, 13, 14, 15, 16, and 17 are schematic cross-sectional views illustrating the method for manufacturing the semiconductor device.

FIG. 18 is a schematic plan view illustrating a semiconductor device of a modified example.

FIG. 19 is a schematic plan view illustrating a semiconductor device of another modified example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

An embodiment will now be described with reference to the drawings.

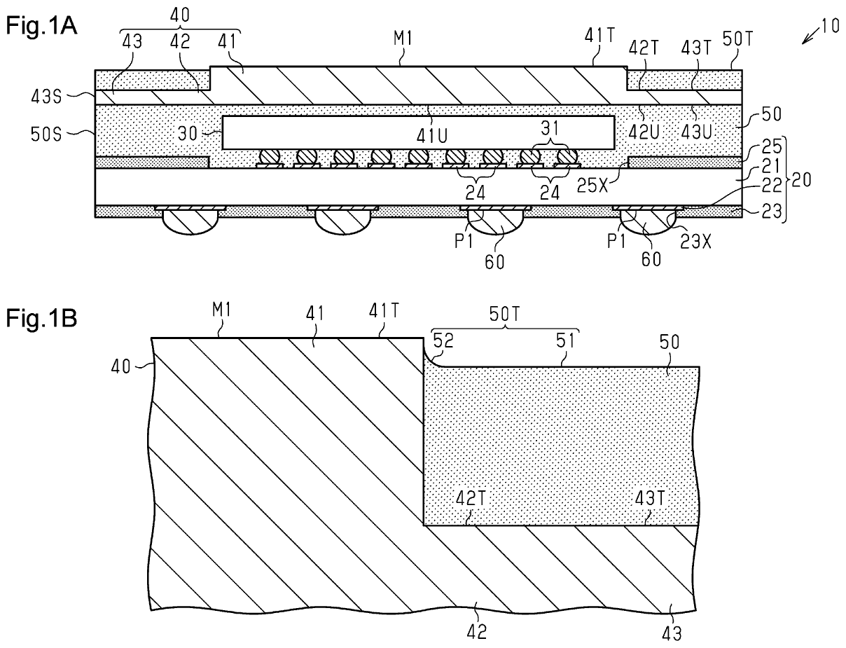

The drawings may not be to scale, and the relative size, proportions, and depiction of elements in the drawings may be exaggerated for clarity, illustration, and convenience. To facilitate understanding, hatching lines may not be illustrated or may be replaced by shadings in the cross-sectional views. In this specification, a plan view refers to a view taken in a vertical direction (e.g., top-bottom direction as viewed in FIG. 1A), and a planar shape refers to a shape of a subject as viewed in the vertical direction. Further, in this specification, “top-bottom direction” and “left-right direction” refer to directions when the drawings are oriented to allow the reference characters denoting members to be read properly. In this specification, the term “face” is used to indicate that surfaces or members are arranged in front of each other. In this case, the objects do not have to be entirely in front of each other and may be partially in front of each other. The term “face” as used in this specification includes a situation in which a member is located between two portions and a situation in which there is no member between two portions. Furthermore, unless otherwise specified, a numerical range of “X1 to X2”, defined by the upper limit value X1 and the lower limit value X2, corresponds to a range that is greater than or equal to X1 and less than or equal to X2.

### Overall Configuration of Semiconductor Device 10

With reference to FIG. 1A, the structure of a semiconductor device 10 will now be described.

The semiconductor device 10 includes a wiring substrate 20, one or more semiconductor elements 30 (one in the present embodiment), a heat dissipation plate 40, an encapsulation resin 50, and external connection terminals 60.

### Structure of Wiring Substrate 20

The wiring substrate 20 includes a substrate body 21. A wiring layer 22 and a solder resist layer 23 are sequentially stacked on a lower surface of the substrate body 21. A wiring layer 24 and a solder resist layer 25 are sequentially formed on an upper surface of the substrate body 21.

The substrate body 21 may be a wiring structure in which insulating resin layers and wiring layers are alternately stacked. For example, such a wiring structure may include a core substrate, but does not have to include a core substrate. The material of the insulating resin layers may be, for example, a thermosetting insulating resin. The thermosetting insulating resin may be, for example, an insulating resin, such as an epoxy resin, a polyimide resin, a cyanate resin, or the like. Furthermore, the material of the insulating resin layers may be, for example, an insulating resin including a photosensitive resin, such as a phenol-based resin, a polyimide-based resin, or the like, as a main component. The insulating resin layers may contain, for example, a filler such as silica, alumina, or the like.

The material of the wiring layers in the substrate body 21 and the material of the wiring layers 22 and 24 may be, for example, copper (Cu) or a copper alloy. The material of the solder resist layers 23 and 25 may be, for example, an insulating resin including a photosensitive resin, such as a phenol-based resin or a polyimide-based resin, as a main component. The solder resist layers 23 and 25 may contain, for example, a filler such as silica, alumina, or the like.

The wiring layer 22 is formed on the lower surface of the substrate body 21. The wiring layer 22 is the lowermost wiring layer of the wiring substrate 20.

The solder resist layer 23 is formed on the lower surface of the substrate body 21 and covers the wiring layer 22. The solder resist layer 23 is the outermost insulating layer (here, lowermost insulating layer) of the wiring substrate 20.

The solder resist layer 23 includes openings 23X that expose parts of a lower surface of the wiring layer 22 as external connection pads P1. The external connection pads P1 are connected to the external connection terminals 60 used when mounting the wiring substrate 20 on a mounting substrate, such as a motherboard or the like.

A surface-processed layer may be formed on the lower surface of the wiring layer 22 exposed at the bottom of each opening 23X. Examples of the surface-processed layer may include a gold (Au) layer, a nickel (Ni) layer/Au layer (metal layer in which the Ni layer serves as bottom layer, and the Au layer is formed on the Ni layer), an Ni layer/palladium (Pd) layer/Au layer (metal layer in which the Ni layer serves as bottom layer, and the Pd layer and the Au layer are sequentially formed on the Ni layer), or the like. Further examples of the surface-processed layer may include a Ni layer/Pd layer (metal layer in which the Ni layer serves as bottom layer, and the Pd layer is formed on the Ni layer), a Pd layer/Au layer (metal layer in which the Pd layer serves as bottom layer, and the Au layer is formed on the Pd layer), or the like. The Au layer is a metal layer of Au or a Au alloy. The Ni layer is a metal layer of Ni or a Ni alloy. The Pd layer is a metal layer of Pd or a Pd alloy. Each of the Au layer, the Ni layer, and the Pd layer may be, for example, a metal layer formed by electroless plating (electroless plating layer) or a metal layer formed by electrolytic plating (electrolytic plating layer). Alternatively, the surface-processed layer may be an organic solderability preservative (OPS) film formed by performing an oxidation-resisting process, such as an OSP process, on the lower surface of the wiring layer 22 exposed from the openings 23X. The OSP film may be an organic coating of an azole compound, an imidazole compound, or the like. When a surface-processed layer is formed on the lower surface of the wiring layer 22, the surface-processed layer functions as the external connection pads P1.

In the present example, the external connection terminals 60 are arranged on the external connection pads P1. Alternatively, the wiring layer 22 exposed at the bottom of each opening 23X (or surface-processed layer formed on wiring layer 22, if any) may be used as external connection terminals.

The wiring layer 24 is formed on the upper surface of the substrate body 21. The wiring layer 24 is the uppermost wiring layer of the wiring substrate 20. The wiring layer 24 is electrically connected to the wiring layer 22, for example, through the wiring layers and through-electrodes formed in the substrate body 21. The wiring layer 24 is arranged in a mounting region where the semiconductor element 30 is mounted. For example, the wiring layer 24 forms a matrix pattern in plan view in correspondence with the layout of bumps 31 arranged on the semiconductor element 30. The wiring layer 24 functions as, for example, electronic component mounting pads for electrical connection with an electronic component, such as the semiconductor element 30.

The solder resist layer 25 is formed on the upper surface of the substrate body 21 and exposes the wiring layer 24. The solder resist layer 25 is the outermost insulating layer (here, uppermost insulating layer) of the wiring substrate 20. For example, in plan view, the solder resist layer 25 surrounds the mounting region where the semiconductor element 30 is mounted. In other words, the solder resist layer 25 includes an open portion 25X that exposes the upper surface of the substrate body 21 and the wiring layer 24 located in the mounting region.

### Structure of Semiconductor Element 30

The semiconductor element 30 includes the bumps 31 formed on a circuit formation surface (here, lower surface) of the semiconductor element 30. The semiconductor element 30 is mounted on an upper surface of the wiring substrate 20. The semiconductor element 30 is flip-chip-mounted on the upper surface of the wiring substrate 20. The semiconductor element 30 is electrically connected to the wiring layer 24 of the wiring substrate 20 through the bumps 31. This electrically connects the semiconductor element 30 to the wiring layer 24 of the wiring substrate 20 through the bumps 31.

The semiconductor element 30 may be, for example, a logic chip, such as a central processing unit (CPU) chip, a graphics processing unit (GPU) chip, or the like. Furthermore, the semiconductor element 30 may be, for example, a memory chip, such as a dynamic random access memory (DRAM) chip, a flash memory chip, or the like. A plurality of semiconductor elements 30 including combinations of logic chips and memory chips may be mounted on the wiring substrate 20.

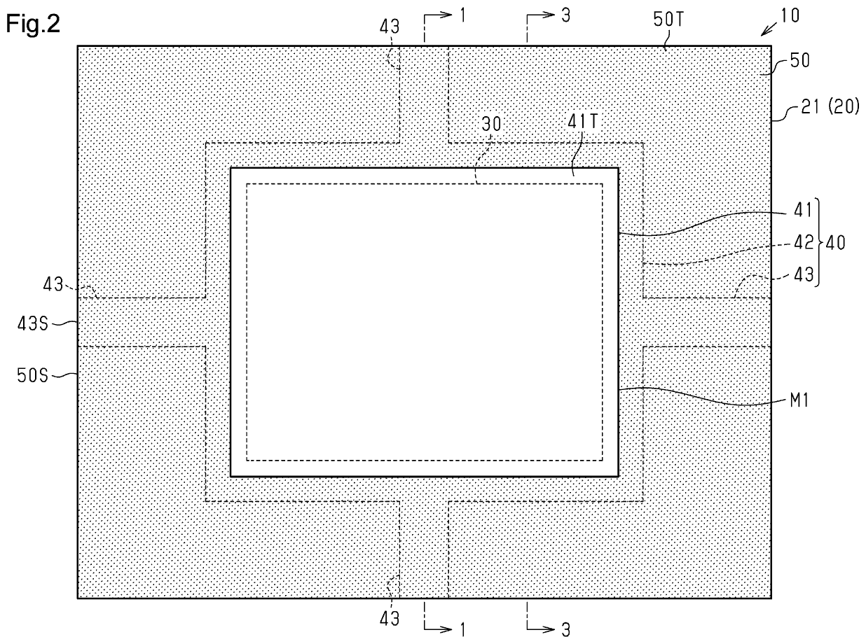

As illustrated in FIG. 2, the semiconductor element 30 has, for example, a rectangular planar shape. The semiconductor element 30 does not have to have a rectangular planar shape and may have any planar shape. The semiconductor element 30 may have a planar size of, for example, approximately 3 mm×3 mm to 12 mm×12 mm. The semiconductor element 30 may have a thickness of, for example, approximately 50 μm to 100 μm.

The bumps 31 illustrated in FIG. 1A may be, for example, gold bumps or solder bumps. The material of solder bumps may be an alloy including lead (Pb), an alloy of tin (Sn) and Au, an alloy of Sn and Cu, an alloy of Sn and silver (Ag), an alloy of Sn, Ag, and Cu, or the like.

### Structure of Heat Dissipation Plate 40

As illustrated in FIG. 1A, the heat dissipation plate 40 is arranged above the semiconductor element 30. For example, the heat dissipation plate 40 is separated from the semiconductor element 30 in a thickness-wise direction of the encapsulation resin 50 (top-bottom direction as viewed in FIG. 1A). For example, the heat dissipation plate 40 is arranged above a back surface (here, upper surface) of the semiconductor element 30 at the side opposite to the circuit formation surface with the encapsulation resin 50 located in between. The heat dissipation plate 40 is also referred to as a heat spreader. The heat dissipation plate 40 functions to disperse the concentration of the heat generated by the semiconductor element 30.

As illustrated in FIGS. 1A and 2, the heat dissipation plate 40 includes, for example, a main body 41, a projection 42, and a plurality of (here, four) leads 43. In the heat dissipation plate 40, the main body 41, the projection 42, and the leads 43 are continuous and integrated with one another.

The main body 41 has the form of, for example, a flat plate. The main body 41 overlaps the semiconductor element 30 in plan view. For example, the main body 41 overlaps the entire semiconductor element 30 in plan view. The main body 41 is, for example, arranged in the mounting region of the semiconductor element 30. As illustrated in FIG. 2, the main body 41 may have the same planar shape as the semiconductor element 30, which is rectangular. That is, the contour of the main body 41 is rectangular in plan view. For example, the main body 41 is slightly larger in size than the semiconductor element 30 in plan view. The main body 41 is smaller in size than the substrate body 21 in plan view. The main body 41 may have a thickness of, for example, approximately 100 μm to 500 μm.

As illustrated in FIG. 1A, the main body 41 includes a lower surface 41U facing the semiconductor element 30, and an upper surface 41T located at the side opposite to the lower surface 41U. The lower surface 41U of the main body 41 is thermally coupled to the back surface of the semiconductor element 30 through the encapsulation resin 50. The upper surface 41T of the main body 41 is exposed from the encapsulation resin 50. For example, the upper surface 41T of the main body 41 is located at a position projecting upward from an upper surface 50T of the encapsulation resin 50. The upper surface 41T of the main body 41 functions as a recognition mark M1, such as an alignment mark. For example, the recognition mark M1 is used when mounting the semiconductor device 10 on another component.

As illustrated in FIG. 2, the projection 42 surrounds the outer edges of the main body 41 in plan view. For example, the projection 42 continuously surrounds the entire periphery of the main body 41.

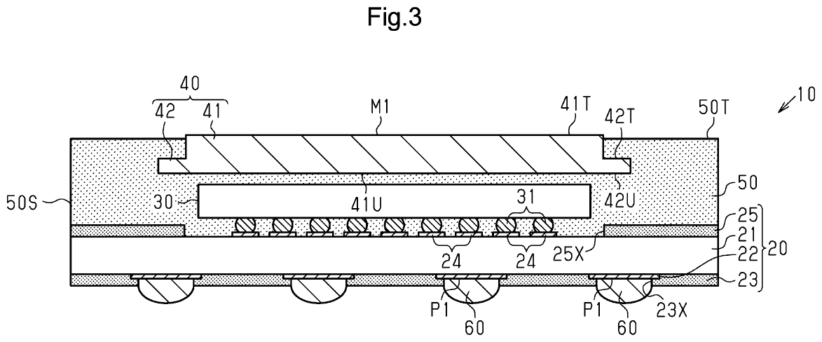

As illustrated in FIG. 3, the projection 42 projects outward from side surfaces of the main body 41. For example, the projection 42 projects toward the outer edges of the semiconductor device 10 from the side surfaces of the main body 41. The projection 42 is, for example, thinner than the main body 41. The projection 42 may have a thickness of, for example, approximately 0.3 to 0.7 times the thickness of the main body 41. The projection 42 may have a thickness of, for example, approximately 50 μm to 200 μm. The projection 42 is a step formed at a position lower than the upper surface 41T of the main body 41. The projection 42 includes an upper surface 42T located downward from the upper surface 41T of the main body 41. The upper surface 42T of the projection 42 is covered by the encapsulation resin 50. The projection 42 includes a lower surface 42U, for example, flush with the lower surface 41U of the main body 41. The lower surface 42U of the projection 42 is covered by the encapsulation resin 50. The projection 42 includes side surfaces covered by the encapsulation resin 50.

As illustrated in FIG. 2, for example, the leads 43 project outward from the side surfaces of the projection 42. For example, the leads 43 project from the side surfaces of the projection 42, which are located toward the outer side of the semiconductor device 10, toward the outer edges of the semiconductor device 10. The leads 43 extend to, for example, outer side surface of the semiconductor device 10.

The leads 43 are arranged, for example, at intervals around the main body 41. The leads 43 are, for example, arranged in a peripheral region of the semiconductor device 10. The leads 43 are spaced apart from one another and arranged at given intervals along the outer edges of the semiconductor device 10. The leads 43 are arranged on, for example, at least two of the four sides of the rectangular contour of the of the main body 41. In the present embodiment, a single lead 43 is arranged on each of the four sides of the contour of the main body 41.

As illustrated in FIG. 1A, each of the leads 43 has, for example, the same thickness as the projection 42. The lead 43 is, for example, thinner than the main body 41. The lead 43 may have a thickness of, for example, approximately 0.3 to 0.7 times the thickness of the main body 41. The lead 43 may have a thickness of, for example, approximately 50 μm to 200 μm. The lead 43 is a step formed at a position lower than the upper surface 41T of the main body 41. The lead 43 includes an upper surface 43T located downward from the upper surface 41T of the main body 41. The upper surface 43T of the lead 43 is, for example, flush with the upper surface 42T of the projection 42. The upper surface 43T of the lead 43 is, for example, covered by the encapsulation resin 50. The lower surface 43U of the lead 43 is, for example, flush with the lower surface 41U of the main body 41 and the lower surface 42U of the projection 42. The lower surface 43U of the lead 43 is, for example, covered by the encapsulation resin 50.

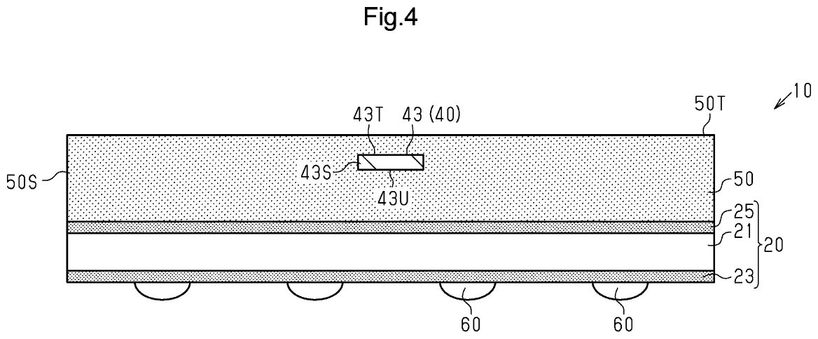

As illustrated in FIGS. 1A and 4, each of the leads 43 includes an outer side surface 43S exposed from an outer side surface 50S of the encapsulation resin 50. In other words, the outer side surface 43S of the lead 43 located at the outer edge of the semiconductor device 10 is exposed from the outer side surface 50S of the encapsulation resin 50. The outer side surface 43S of the lead 43 is, for example, flush with the outer side surface 50S of the encapsulation resin 50. As illustrated in FIG. 2, the encapsulation resin 50 covers the lead 43 except for the outer side surface 43S.

### Structure of Encapsulation Resin 50

As illustrated in FIG. 1A, the encapsulation resin 50 encapsulates the semiconductor element 30 and fills a gap between the wiring substrate 20 and the heat dissipation plate 40. The encapsulation resin 50 is formed on the upper surface of the substrate body 21. For example, the encapsulation resin 50 entirely covers the semiconductor element 30 including the bumps 31. For example, the encapsulation resin 50 covers the entire surfaces of the semiconductor element 30. For example, the encapsulation resin 50 fills a gap between the wiring substrate 20 and the semiconductor element 30. For example, the encapsulation resin 50 entirely covers the upper surface of the substrate body 21 and the wiring layer 24 that are exposed in the open portion 25X of the solder resist layer 25.

The encapsulation resin 50 fills a gap between the semiconductor element 30 and the heat dissipation plate 40. The interval between the back surface (here, upper surface) of the semiconductor element 30 and the lower surface of the heat dissipation plate 40, in particular, the shortest distance between the back surface of the semiconductor element 30 and the lower surface of the heat dissipation plate 40, may be, for example, approximately 40 μm to 100 μm. The gap between the back surface of the semiconductor element 30 and the lower surface of the heat dissipation plate 40 includes, for example, only the encapsulation resin 50. In other words, the heat dissipation plate 40 is arranged above the semiconductor element 30 with only the encapsulation resin 50 located in between. The heat dissipation plate 40 is thermally coupled to the semiconductor element 30 through only the encapsulation resin 50. The encapsulation resin 50 filling the gap between the semiconductor element 30 and the heat dissipation plate 40 covers the entire lower surface 41U of the main body 41.

The encapsulation resin 50 fills, for example, a gap between the solder resist layer 25 and the heat dissipation plate 40. For example, the gap between the upper surface of the solder resist layer 25 and the lower surface of the heat dissipation plate 40 includes only the encapsulation resin 50 and does not include a spacer that maintains the interval between the wiring substrate 20 and the heat dissipation plate 40 at a given distance. That is, in a portion outside the mounting region of the semiconductor element 30, only the encapsulation resin 50 is arranged in the gap between the wiring substrate 20 and the heat dissipation plate 40. In other words, the heat dissipation plate 40 is arranged above the wiring substrate 20 with only the encapsulation resin 50 located in between. The heat dissipation plate 40 is supported above the wiring substrate 20 by only the encapsulation resin 50. The encapsulation resin 50 covers, for example, the entire upper surface of the solder resist layer 25.

The encapsulation resin 50 embeds the projection 42 and the leads 43 of the heat dissipation plate 40 in a peripheral region outside the mounting region. The encapsulation resin 50 embeds at least the upper surfaces 42T and 43T and the lower surfaces 42U and 43U of the projection 42 and each lead 43. In particular, the encapsulation resin 50 covers the entire upper surface 42T of the projection 42, the entire lower surface 42U of the projection 42, and the entire side surfaces of the projection 42. The encapsulation resin 50 covers the entire upper surface 43T of the lead 43, the entire lower surface 43U of the lead 43, and the entire side surfaces of the lead 43 except for the outer side surface 43S.

The outer side surface 50S of the encapsulation resin 50 exposes the outer side surface 43S of the lead 43. The outer side surface 50S of the encapsulation resin 50 is, for example, flush with the outer side surface 43S of the lead 43, an outer side surface of the substrate body 21, and outer side surfaces of the solder resist layers 23 and 25.

The encapsulation resin 50 covers part of the side surfaces of the main body 41 in the thickness-wise direction of the main body 41 (top-bottom direction as viewed in FIG. 1A). The encapsulation resin 50 covers a lower portion of the side surfaces of the main body 41. The encapsulation resin 50 continuously covers the side surfaces of the main body 41 along the entire periphery of the main body 41. The encapsulation resin 50 exposes an upper portion of the side surfaces of the main body 41. The encapsulation resin 50 exposes an entirety of the upper surface 41T of the main body 41.

As illustrated in FIG. 1B, the upper surface 50T of the encapsulation resin 50 is located downward from the upper surface 41T of the main body 41. This forms a step between the upper surface 50T of the encapsulation resin 50 and the upper surface 41T of the main body 41. The distance between the upper surface 50T and the upper surface 41T in the thickness-wise direction of the encapsulation resin 50 (top-bottom direction as viewed in FIG. 1B) may be, for example, approximately 1 μm to 30 μm.

The upper surface 50T includes, for example, a flat portion 51 and a sloped portion 52. In the upper surface 50T, for example, the flat portion 51 and the sloped portion 52 are continuous and integrated with each other.

The flat portion 51 extends, for example, horizontally in a planar direction (left-right direction in FIG. 1B) that is orthogonal to the thickness-wise direction of the encapsulation resin 50. The flat portion 51 extends, for example, parallel to the upper surface 41T of the main body 41.

The sloped portion 52 is arranged around the main body 41. The sloped portion 52 is located between the flat portion 51 and the side surfaces of the main body 41. The sloped portion 52 is in contact with the side surfaces of the main body 41. For example, the sloped portion 52 surrounds the main body 41 in plan view. The sloped portion 52 is sloped downward from the side surfaces of the main body 41 toward the flat portion 51. The sloped portion 52 is sloped downward as the sloped portion 52 extends away from the side surfaces of the main body 41. The sloped portion 52 is, for example, curved. The sloped portion 52 is, for example, a curved surface curved in an arcuate manner or an elliptic manner. The sloped portion 52 may be sloped linearly in cross-sectional view. That is, the sloped portion 52 may be inclined at a constant inclination angle.

As illustrated in FIG. 1A, the encapsulation resin 50 fixes the heat dissipation plate 40 to the wiring substrate 20 and encapsulates the semiconductor element 30. Thus, the encapsulation resin 50 functions as a support that supports the heat dissipation plate 40 on the wiring substrate 20 and a protector that protects the semiconductor element 30. Further, the encapsulation resin 50 increases the overall mechanical strength of the semiconductor device 10. This allows for reduction in thickness of the wiring substrate 20 and the heat dissipation plate 40, which, in turn, reduces the total thickness of the semiconductor device 10.

The material of the encapsulation resin 50 may be, for example, a non-photosensitive insulating resin including a thermosetting resin as a main component. The material of the encapsulation resin 50 may be, for example, an insulating resin, such as an epoxy-based resin, a polyimide-based resin or the like, or a resin material obtained by mixing the insulating resin with a filler, such as silica, alumina, or the like. The encapsulation resin 50 may be, for example, a mold resin.

### Structure of External Connection Terminal 60

The external connection terminals 60 are formed on the external connection pads P1 of the wiring substrate 20. The external connection terminals 60 are, for example, connection terminals for electrical connection with pads arranged on a mounting substrate, such as a motherboard (not illustrated). The external connection terminals 60 may be, for example, solders ball or lead pins. In the present embodiment, the external connection terminals 60 are solder balls.

### Method for Manufacturing Semiconductor Device 10

A method for manufacturing the semiconductor device 10 will now be described. To facilitate understanding, portions that will become final elements of the semiconductor device 10 are given the same reference characters as the final elements.

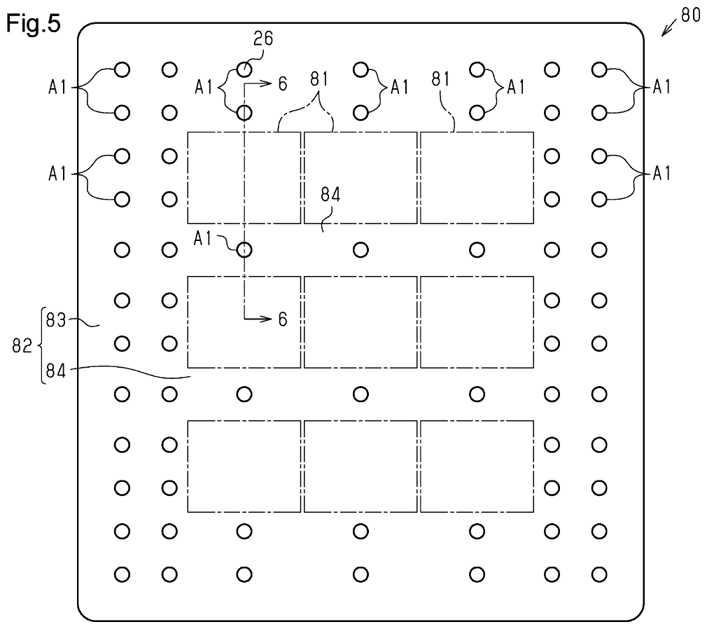

First, in the step illustrated in FIG. 5, a relatively large first substrate 80 is prepared. The first substrate 80 includes a plurality of first product regions 81 and a first non-product region 82. In the first substrate 80, for example, the first product regions 81 are arranged in a matrix pattern (here, three rows×three columns). A structure corresponding to the wiring substrate 20 illustrated in FIG. 1A is formed in each of the first product regions 81. The first non-product region 82 surrounds the nine first product regions 81 in plan view. For example, the first non-product region 82 surrounds each of the nine first product regions 81 in plan view. The first non-product region 82 includes, for example, a first peripheral region 83 that collectively surrounds the nine first product regions 81, and first joining regions 84 that are each located between two adjacent ones of the first product regions 81 in the top-bottom direction as viewed in FIG. 5. The first joining regions 84 each extend in the left-right direction as viewed in FIG. 5.

Subsequent to formation of a structure corresponding to the semiconductor device 10 illustrated in FIG. 1A in each of the first product regions 81, the first substrate 80 is cut along cutting lines, which are indicated by the single-dashed lines, and singulated into separate semiconductor devices 10. Thus, the portion outside the first product regions 81, namely, the first non-product region 82, is consequently disposed of. In other words, the first non-product region 82 is a portion that will consequently be removed from the singulated semiconductor devices 10. In the example illustrated in FIG. 5, the first substrate 80 includes nine first product regions 81. However, there is no limitation to the quantity of first product regions 81. To facilitate understanding, the description hereafter will focus on a single first product region 81 and the first non-product region 82 surrounding the first product region 81.

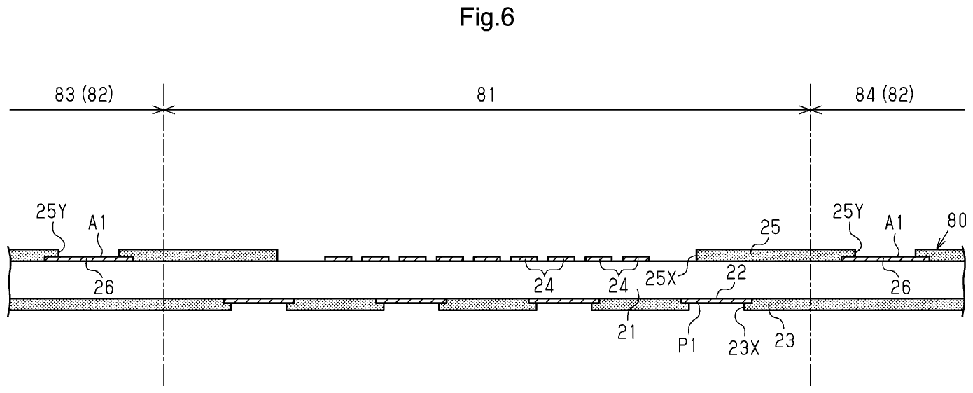

As illustrated in FIG. 6, each first product region 81 of the first substrate 80 includes the substrate body 21, the wiring layer 22 and the solder resist layer 23, which are stacked on the lower surface of the substrate body 21, and the wiring layer 24 and the solder resist layer 25, which are stacked on the upper surface of the substrate body 21. In this case, a wiring layer 26 is formed on the upper surface of the substrate body 21 in the first non-product region 82 of the first substrate 80. The solder resist layer 25 arranged in the first non-product region 82 includes openings 25Y that expose parts of the upper surface of the wiring layer 26 as first connecting portions A1. As illustrated in FIG. 5, for example, lines of the first connecting portions A1 are arranged in a peripheral manner in the first peripheral region 83 of the first non-product region 82. In particular, the lines of the first connecting portions A1 in the first peripheral region 83 are arranged along the outer edges of the first substrate 80. The first connecting portions A1 are also arranged in the first joining regions 84 of the first non-product region 82. The first connecting portions A1 in the first joining regions 84 are each arranged between two adjacent ones of the first product regions 81 in the top-bottom direction as viewed in FIG. 5.

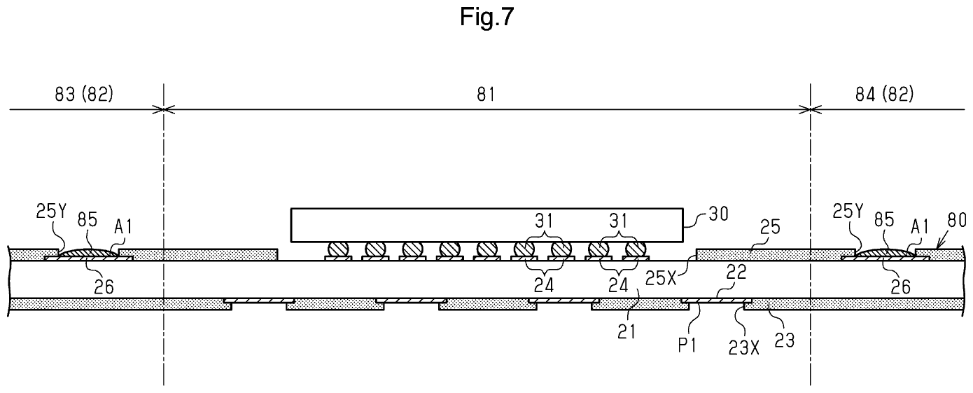

Then, in the step illustrated in FIG. 7, a solder layer 85 is formed on the upper surface of the wiring layer 26 exposed in each opening 25Y of the solder resist layer 25, that is, on the first connecting portion A1. For example, screen printing or the like may be performed to apply a paste to the first connecting portions A1 to form the solder layer 85.

In the step illustrated in FIG. 7, the semiconductor element 30 is prepared. The semiconductor element 30 includes the bumps 31 formed on the circuit formation surface (here, lower surface). Then, the semiconductor element 30 is mounted on the upper surface of the wiring layer 24 in the first product region 81. For example, the bumps 31 of the semiconductor element 30 are flip-chip bonded to the wiring layer 24 in the first product region 81. In particular, when the bumps 31 are solder bumps, flux (not illustrated) is applied to the wiring layer 24. Further, the wiring layer 24 is aligned with the bumps 31. Then, reflow soldering is performed at a temperature of approximately 230° C. to 260° C. This melts the bumps 31, which are solder bumps, and electrically connects the bumps 31 to the wiring layer 24.

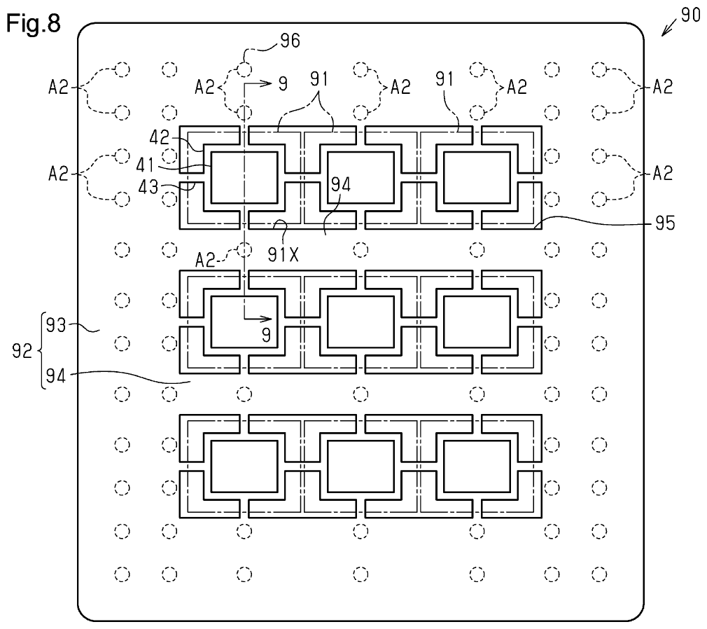

Then, in the step illustrated in FIG. 8, a relatively large second substrate 90 is prepared. The second substrate 90 is, for example, a metal plate. In the present embodiment, the second substrate 90 is a copper plate. The second substrate 90 includes second product regions 91 and a second non-product region 92. In the second substrate 90, for example, the second product regions 91 are arranged in a matrix pattern (here, three rows×three columns). A structure corresponding to the heat dissipation plate 40 illustrated in FIG. 1A is formed in each of the second product regions 91. The second non-product region 92 surrounds the nine second product regions 91 in plan view. For example, the second non-product region 92 surrounds each of the nine second product regions 91 in plan view. The second non-product region 92 includes, for example, a second peripheral region 93 that collectively surrounds the nine second product regions 91, and second joining regions 94 that are each located between two adjacent ones of the second product regions 91 in the top-bottom direction as viewed in FIG. 8. The second joining regions 94 each extend in the left-right direction as viewed in FIG. 8.

Subsequent to formation of a structure corresponding to the semiconductor device 10 illustrated in FIG. 1A in each of the second product regions 91, the second substrate 90 is cut along cutting lines, which are indicated by the single-dashed lines, and singulated into separate semiconductor devices 10. Thus, the portion outside the second product regions 91, namely, the second non-product region 92, is consequently disposed of. In other words, the second non-product region 92 is a portion that will consequently be removed from the singulated semiconductor devices 10. In the example illustrated in FIG. 8, the second substrate 90 includes nine second product regions 91. However, there is no limitation to the quantity of second product regions 91. To facilitate understanding, the description hereafter will focus on a single second product region 91 and the second non-product region 92 surrounding the second product region 91.

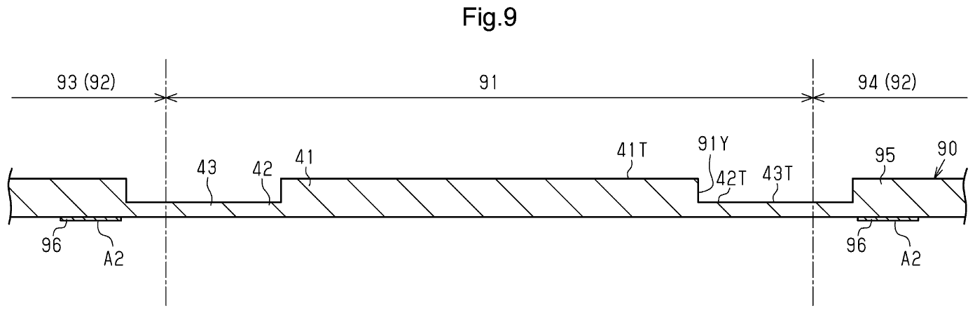

As illustrated in FIGS. 8 and 9, each second product region 91 of the second substrate 90 includes the main body 41, the projection 42, and the leads 43. In other words, as illustrated in FIG. 8, openings 91X are formed in each second product region 91 to define the main body 41, the projection 42, and the leads 43. As illustrated in FIG. 9, the second product region 91 includes recesses 91Y that define the upper surface 42T of the projection 42 and the upper surface 43T of the leads 43. Thus, in the present example, the projection 42 and the leads 43 are obtained by reducing the thickness of the second substrate 90 from its upper surface. The openings 91X and the recesses 91Y described above may be formed by, for example, etching or pressing.

As illustrated in FIG. 8, the second joining regions 94 of the second non-product region 92 include joining portions 95 that each connect the leads 43 of two adjacent ones of the second product regions 91 in the top-bottom direction as viewed in FIG. 8. In other words, the leads 43 formed in each of the second product regions 91 are connected by the joining portion 95 to the leads 43 formed in the adjacent one of the second product regions 91 in the top-bottom direction as viewed in FIG. 8. Further, the leads 43 formed in each of the second product regions 91 are, for example, directly connected to the leads 43 formed in the adjacent one of the second product regions 91 in the left-right direction as viewed in FIG. 8.

In the step illustrated in FIG. 9, a metal layer 96 is formed on the lower surface of the second substrate 90 in the second non-product region 92. In the present example, the metal layer 96 is formed on parts of the lower surface of the second substrate 90 in the second non-product region 92. The metal layer 96 may be formed, for example, by electrolytic plating that uses the second substrate 90 as a power feeding layer. For example, a resist layer is formed on the entire surfaces of the second substrate 90 except for the formation regions of the metal layer 96. Then, electrolytic plating is performed using the resist layer as a plating mask to form the metal layer 96 on the second substrate 90 that is exposed from the resist layer. Alternatively, the metal layer 96 may be formed by a sparger process. Examples of the metal layer 96 may include an Ag layer, a Au layer, a Ni layer, a Ni layer/Au layer, a Ni layer/Pd layer/Au layer, or a Ni layer/Ag layer. In the present embodiment, the outermost layer of the metal layer 96 is, for example, a noble metal plating layer, such as a Au layer, a Ag layer, a Pd layer, or the like. The outermost layer of the metal layer 96, that is, the lower surface of the metal layer 96, functions as second connecting portions A2 for connection with the first connecting portions A1 of the first substrate 80 illustrated in FIG. 7. The second connecting portions A2 are arranged in correspondence with the first connecting portions A1.

As illustrated in FIG. 8, for example, lines of the second connecting portions A2 are arranged in a peripheral manner in the second peripheral region 93 of the second non-product region 92. In particular, the lines of the second connecting portions A2 in the second peripheral region 93 are arranged along the outer edges of the second substrate 90. The second connecting portions A2 are also arranged in the joining portions 95 of the second joining regions 94. The second connecting portions A2 in the joining portions 95 are each arranged between two adjacent ones of the second product regions 91 in the top-bottom direction as viewed in FIG. 8.

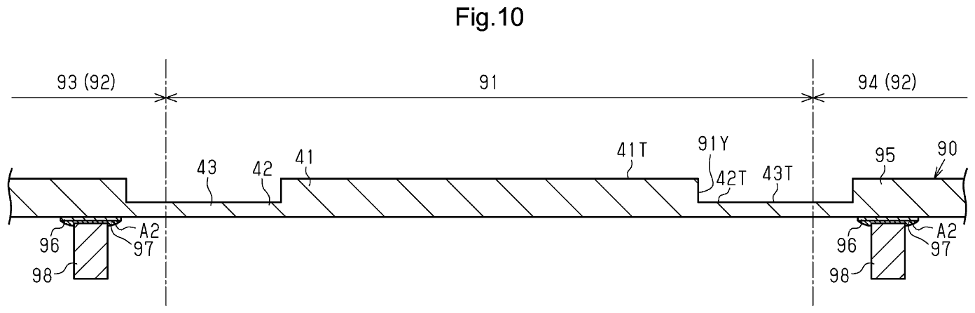

In the step illustrated in FIG. 10, a solder layer 97 is formed on the lower surface of the metal layer 96, that is, on the second connecting portions A2. For example, screen printing or the like may be performed to apply a paste to the second connecting portions A2 to form the solder layer 97. Then, rod-shaped metal posts 98 are mounted on (bonded to) the second connecting portions A2. For example, the metal posts 98 are mounted on the solder layer 97, and reflow soldering is performed at a given temperature to melt the solder layer 97 and fix the metal posts 98 to the second connecting portions A2. The outermost layer of the metal layer 96 is a noble metal plating layer. This allows the solder to be wet-spread on the metal layer 96 in a preferred manner. The material of the metal posts 98 may be, for example, copper or a copper alloy.

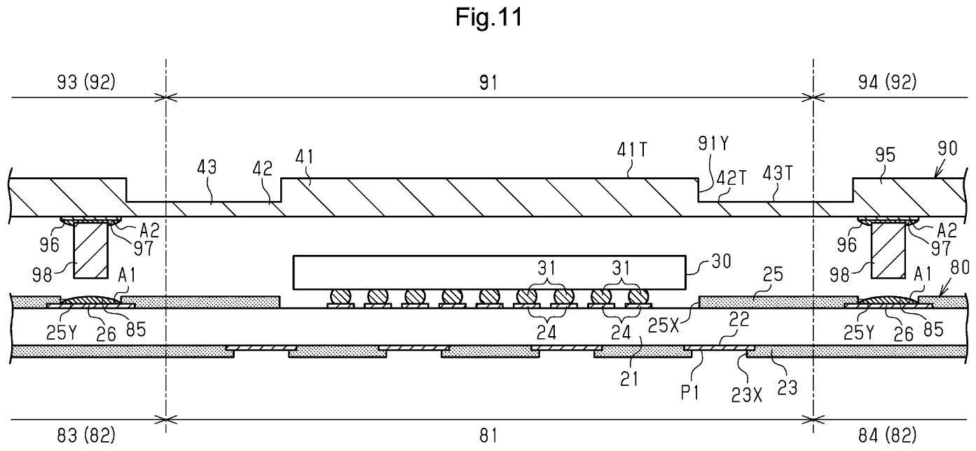

Next, in the step illustrated in FIG. 11, the second substrate 90 is arranged above the first substrate 80. In this case, the first substrate 80 and the second substrate 90 are arranged so that the first product regions 81 overlap the second product regions 91 in plan view. That is, the first substrate 80 and the second substrate 90 are arranged so as to align the first product regions 81 and the second product regions 91 in the vertical direction. Further, the first substrate 80 and the second substrate 90 are arranged so that the first connecting portions A1 of the first substrate 80 face the second connecting portions A2 and the metal posts 98 of the second substrate 90.

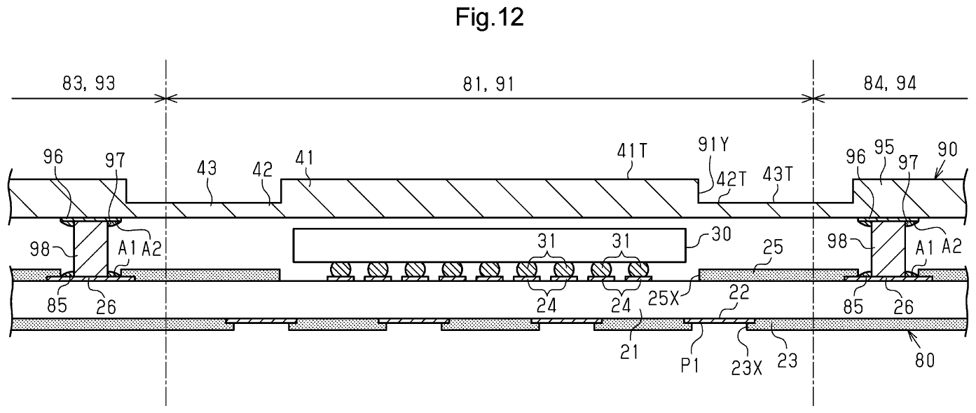

Then, in the step illustrated in FIG. 12, the first connecting portions A1 and the second connecting portions A2 are connected by the metal posts 98 so that the second substrate 90 is mounted on the first substrate 80. For example, flux is applied to the solder layer 85 of the first substrate 80. Then, the second substrate 90 is arranged on the first substrate 80 with the metal posts 98 sandwiched in between. The first substrate 80 and the second substrate 90 placed one upon the other are pressed and heated at a temperature of approximately 230° C. to 260° C. This melts the solder layers 85 and 97 and bonds the metal posts 98 to the first connecting portions A1 and the second connecting portions A2. In this step, the second substrate 90 is fixed to the first substrate 80 by the metal posts 98, and the first connecting portions A1 are electrically connected to the second connecting portions A2 by the metal posts 98. In this step, reflow soldering is performed while pressing the second substrate 90 toward the first substrate 80 with the metal posts 98 functioning as spacers. This allows the interval between the first substrate 80 and the second substrate 90 to be maintained at a given distance.

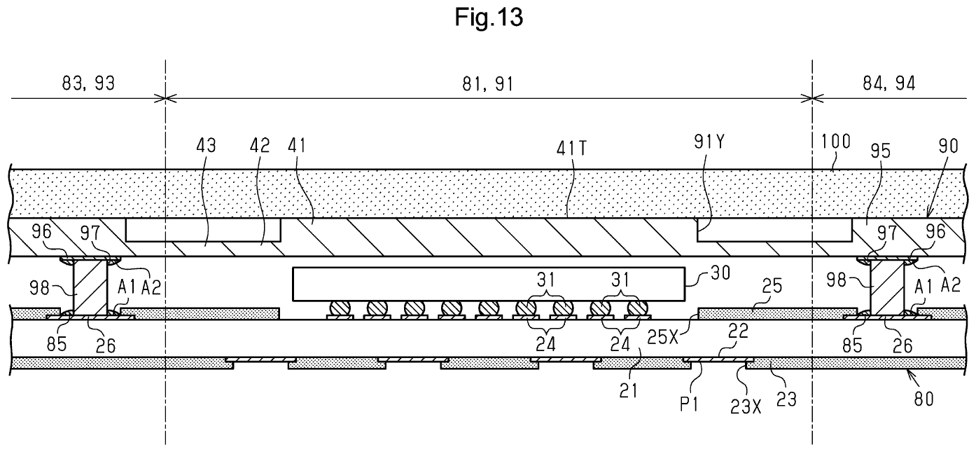

In the step illustrated in FIG. 13, an adhesive film 100 is attached to the upper surface of the second substrate 90. For example, the adhesive film 100 is arranged on the upper surface of the second substrate 90 so as to close the recesses 91Y. For example, the adhesive film 100 is arranged on the upper surface of the second substrate 90 so as to close the upper side of the openings 91X illustrated in FIG. 8. The material of the adhesive film 100 may be, for example, a material having superior chemical resistance and superior thermal resistance. The material of the adhesive film 100 may be, for example, a material having superior flexibility. The adhesive film 100 may be, for example, a polytetrafluoroethylene (PTFE) film or a polyethylene terephthalate (PET) film.

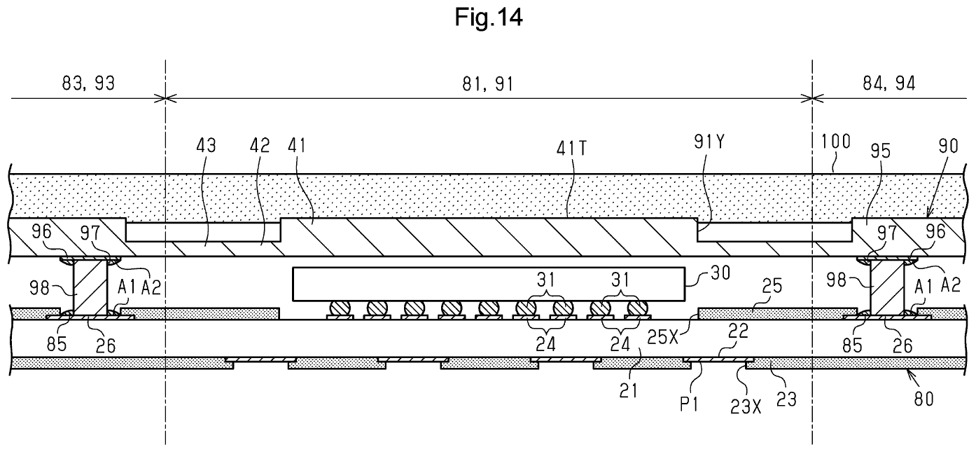

Subsequently, in the step illustrated in FIG. 14, the adhesive film 100 is pressed against the second substrate 90 so that an upper portion of the second substrate 90 is embedded in the adhesive film 100. In this step, the adhesive film 100 is arranged to incorporate the upper portion of the second substrate 90, for example, the upper portion of the main body 41. The adhesive film 100 covers the upper portion of the side surfaces of the main body 41. In other words, the adhesive film 100 is arranged to cover part of the wall surfaces of the recesses 91Y. That is, this step pushes the adhesive film 100 into the recesses 91Y. In this manner, in the steps illustrated in FIGS. 13 and 14, the adhesive film 100 is applied to the upper surface of the second substrate 90 so that the upper portion of the second substrate 90 is embedded in the adhesive film 100.

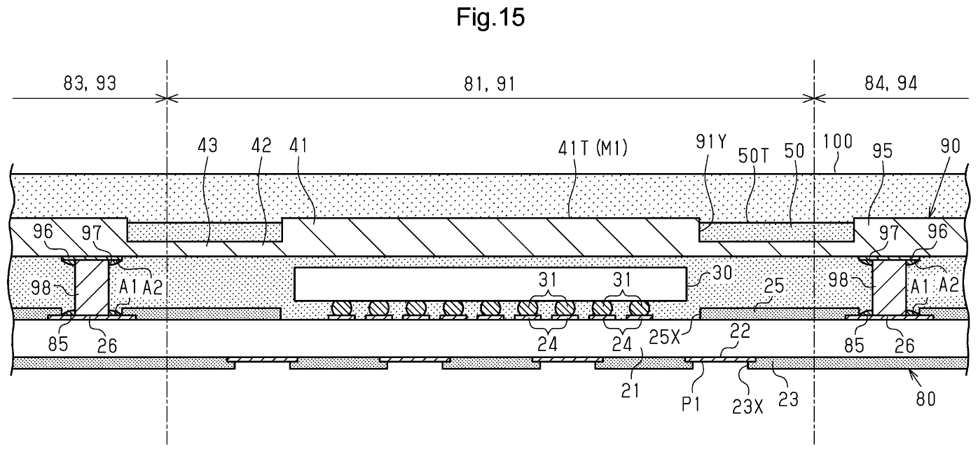

Then, in the step illustrated in FIG. 15, the encapsulation resin 50 is formed filling the gap between the first substrate 80 and the second substrate 90. The encapsulation resin 50 fills the gap between the first substrate 80 and the semiconductor element 30 and the gap between the semiconductor element 30 and the second substrate 90. The encapsulation resin 50 fills the recesses 91Y exposed from the adhesive film 100. The encapsulation resin 50 fills the openings 91X (refer to FIG. 8) exposed from the adhesive film 100. The encapsulation resin 50 may be formed by, for example, a resin molding process. For example, when a thermosetting mold resin is used as the material of the encapsulation resin 50, the structure illustrated in FIG. 14 is arranged in a mold. Then, the mold resin is liquified and injected into the mold under a pressure (e.g., 5 MPa to 10 MPa). The mold resin is heated at a temperature of approximately 180° C. and cured to form the encapsulation resin 50. After the encapsulation process is completed, the structure including the encapsulation resin 50 is removed from the mold. The process for filling the mold with the mold resin may be, for example, transfer molding, compression molding, injection molding, or the like.

During the encapsulation process in the present step, the adhesive film 100 acts to limit leakage of the mold resin (also referred to as “mold flash”) onto the upper surface of the second substrate 90. However, even when such an adhesive film 100 is arranged, the mold resin may enter into the gap between the adhesive film 100 and the second substrate 90. If the upper surface 50T of the encapsulation resin 50 were to be flush with the upper surface 41T of the main body 41, the adhesive film 100 would be arranged on the upper surface 41T of the main body 41. In this case, if the mold resin were to enter the gap between the lower surface of the adhesive film 100 and the upper surface 41T of the main body 41, a resin coating would be formed on part of the upper surface 41T of the main body 41. Such formation of the resin coating would weaken the contrast between the upper surface 41T of the main body 41 and the upper surface 50T of the encapsulation resin 50. Accordingly, if the upper surface 41T of the main body 41 were to be used as the recognition mark M1, visual recognition of the recognition mark M1 would be impaired.

In contrast, in the present embodiment, the adhesive film 100 is arranged so as to embed the upper portion of the second substrate 90, for example the upper portion of the main body 41. This forms a step between the lower surface of the adhesive film 100 and the upper surface 41T of the main body 41. Accordingly, the distance to the upper surface 41T of the main body 41 through the gap between the adhesive film 100 and the second substrate 90 is increased to be greater than when the upper surface 50T of the encapsulation resin 50 is flush with the upper surface 41T of the main body 41. Therefore, even when the mold resin enters into the gap between the adhesive film 100 and the second substrate 90, the mold resin will not leak onto the upper surface 41T of the main body 41. The step formed between the upper surface 41T of the main body 41 and the upper surface 50T of the encapsulation resin 50 appropriately avoids spreading of the mold resin onto the upper surface 41T of the main body 41.

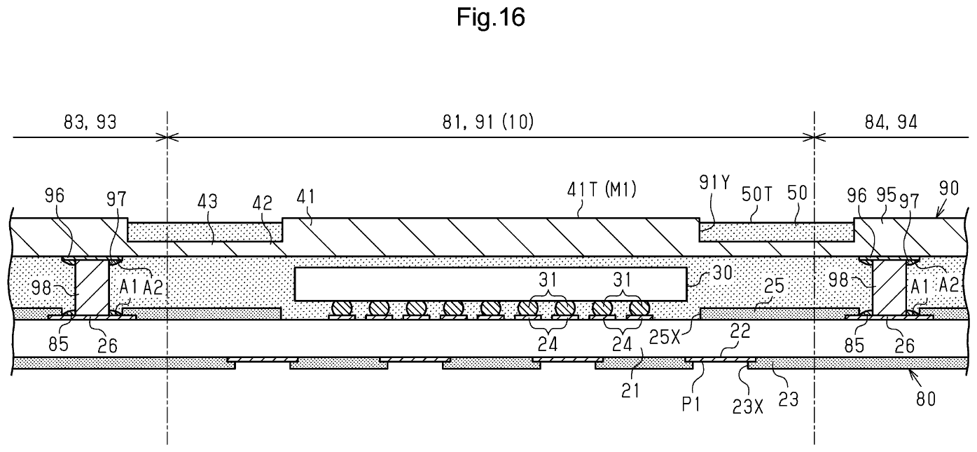

Next, in the step illustrated in FIG. 16, the adhesive film 100 illustrated in FIG. 15 is removed. This exposes the upper portion of the second substrate 90, which was embedded in the adhesive film 100, and the upper surface 50T of the encapsulation resin 50 to the outside.

A structure corresponding to the semiconductor device 10 is formed in each of the first product regions 81 and the corresponding second product regions 91 through the manufacturing steps described above.

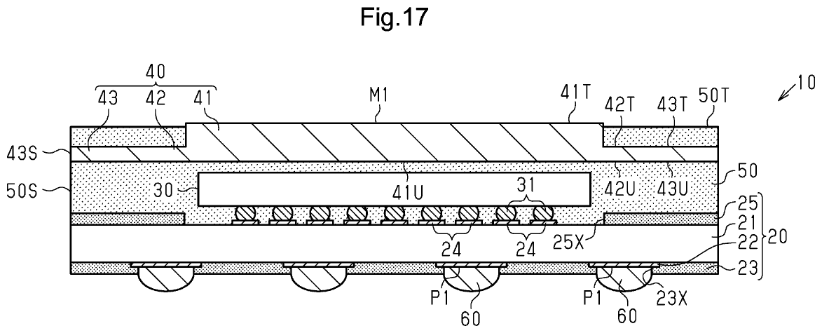

Then, the first substrate 80, the second substrate 90, and the encapsulation resin 50 are cut with a dicing saw or the like along cutting lines, which are indicated by the single-dashed lines in FIG. 16, that is, along the edges of the first product regions 81 and the edges of the second product regions 91, and singulated into separate semiconductor devices 10. In this step, as illustrated in FIG. 17, the cut surfaces, namely, the outer side surface 43S of the lead 43, the outer side surface 50S of the encapsulation resin 50, and the outer side surface of the substrate body 21 are flush with one another. Further, this step removes the first non-product region 82 and the second non-product region 92 including the metal posts 98 illustrated in FIG. 16.

A batch of the semiconductor devices 10 is manufactured through the manufacturing steps described above. The singulated semiconductor devices 10 may be used in an upside-down state or arranged at any angle.

The operation and advantages of the present embodiment will now be described.

(1) The semiconductor device 10 includes the wiring substrate 20, the semiconductor element 30 mounted on the wiring substrate 20, and the heat dissipation plate 40 arranged above the semiconductor element 30. The semiconductor device 10 includes the encapsulation resin 50 that encapsulates the semiconductor element 30 and fills the gap between the wiring substrate 20 and the heat dissipation plate 40. The heat dissipation plate 40 includes the main body 41 that overlaps the semiconductor element 30 in plan view. The encapsulation resin 50 covers part of the side surfaces of the main body 41. The upper surface 50T of the encapsulation resin 50 is located downward from the upper surface 41T of the main body 41. The encapsulation resin 50 exposes the entirety of the upper surface 41T of the main body 41 and the upper portion of the side surfaces of the main body 41.

With this structure, the upper surface 50T of the encapsulation resin 50 is located downward from the upper surface 41T of the main body 41 such that a step is formed between the upper surface 50T of the encapsulation resin 50 and the upper surface 41T of the main body 41. Accordingly, the step between the main body 41 and the encapsulation resin 50 extends along the contour (outer edges) of the upper surface 41T of the main body 41. Thus, when the contour of the upper surface 41T of the main body 41 is detected with a recognition camera or the like as the recognition mark M1, the contrast between the upper surface 41T of the main body 41 and the upper surface 50T of the encapsulation resin 50 may be readily recognized. This allows the contour of the upper surface 41T of the main body 41 to be readily recognized, thereby improving visual recognition of the recognition mark M1.

(2) In addition, when forming the encapsulation resin 50, the step between the upper surface 50T of the encapsulation resin 50 and the upper surface 41T of the main body 41 avoids spreading of the mold resin onto the upper surface 41T of the main body 41. Thus, a resin coating will not be formed to cover part of the upper surface 41T of the main body 41. This enhances the contrast between the upper surface 41T of the main body 41 and the upper surface 50T of the encapsulation resin 50 as compared to when a resin coating is formed on the upper surface 41T of the main body 41. As a result, visual recognition of the recognition mark M1 is improved.

(3) The upper surface 50T of the encapsulation resin 50 includes the sloped portion 52 contacting the side surfaces of the main body 41. The sloped portion 52 is sloped downward as the sloped portion 52 extends away from the side surfaces of the main body 41. With this structure, when light is emitted from above the semiconductor device 10 onto the upper surfaces 41T and 50T so as to detect the recognition mark M1, the sloped portion 52 diffuses and reflects the light (diffuse reflection). This enhances the contrast between the upper surface 41T of the main body 41 and the upper surface 50T of the encapsulation resin 50. As a result, visual recognition of the recognition mark M1 is further improved.

(4) The sloped portion 52 is in contact with the side surfaces of the main body 41. This increases the area of contact between the encapsulation resin 50 and the side surfaces of the main body 41 as compared to a structure in which the upper surface 50T of the encapsulation resin 50 includes only the flat portion 51. This improves the adhesion between the encapsulation resin 50 and the heat dissipation plate 40.

(5) The area of contact between the encapsulation resin 50 and the side surfaces of the main body 41 is increased. Thus, even when a thermal stress is applied to the interface between the encapsulation resin 50 and the main body 41 during a thermal cycling reliability test or the like, the thermal stress will be dispersed in a preferred manner. This appropriately avoids cracking of the interface between the encapsulation resin 50 and the main body 41, which would be caused by the thermal stress.

(6) The sloped portion 52 is a curved surface curved in an arcuate manner. With this structure, the interface between the heat dissipation plate 40 and the encapsulation resin 50 is the curved surface. Thus, even when a thermal stress is applied to the interface between the heat dissipation plate 40 and the encapsulation resin 50, the curved surface will disperse the thermal stress in a preferred manner. This avoids cracking of the interface between the heat dissipation plate 40 and the encapsulation resin 50, which would be caused by the thermal stress.

(7) The upper surface 41T of the main body 41 is exposed from the encapsulation resin 50. With this structure, the heat generated by the semiconductor element 30 is transferred through the encapsulation resin 50 to the heat dissipation plate 40, and is dissipated into the atmosphere from the upper surface 41T of the main body 41 of the heat dissipation plate 40. This dissipates the heat generated by the semiconductor element 30 more efficiently than when the upper surface 41T of the main body 41 is covered by the encapsulation resin 50.

(8) The upper surface 43T and the lower surface 43U of each lead 43 are covered by the encapsulation resin 50. Thus, the leads 43 are embedded in the encapsulation resin 50. Accordingly, an anchor effect improves the adhesion between the leads 43 and the encapsulation resin 50. This avoids delamination of the heat dissipation plate 40 including the leads 43 from the encapsulation resin 50. As a result, the heat dissipation performance of the semiconductor device 10 is appropriately maintained.

(9) Further, when the leads 43 are embedded in the encapsulation resin 50, warping of the heat dissipation plate 40 including the leads 43 will be restricted. This avoids delamination of the heat dissipation plate 40 from the encapsulation resin 50, which would be caused by the warping.

(10) The outer side surface 43S of each lead 43 is exposed from the encapsulation resin 50. With this structure, the heat generated by the semiconductor element 30 is transferred through the encapsulation resin 50 to the heat dissipation plate 40 and dissipated into the atmosphere from the outer side surface 43S of the leads 43 of the heat dissipation plate 40. This dissipates the heat generated by the semiconductor element 30 more efficiently than when the outer side surface 43S of each lead 43 is covered by the encapsulation resin 50.

(11) The heat dissipation plate 40 includes the projection 42 projecting outward from the side surfaces of the main body 41. The projection 42 surrounds the main body 41 in plan view. The projection 42 is thinner than the main body 41. The encapsulation resin 50 covers the upper surface 42T and side surfaces of the projection 42.

With this structure, the upper surface, the lower surface, and the side surfaces of the projection 42 are covered by the encapsulation resin 50. Thus, the projection 42 surrounding the main body 41 is embedded in the encapsulation resin 50. Accordingly, an anchor effect improves the adhesion between the projection 42 and the encapsulation resin 50. This appropriately avoids delamination of the heat dissipation plate 40 including the projection 42 from the encapsulation resin 50. As a result, the heat dissipation performance of the semiconductor device 10 is maintained in a preferred manner.

(12) The heat dissipation plate 40 is supported above the wiring substrate 20 by only the encapsulation resin 50. In other words, the semiconductor device 10 includes no connecting members (spacers), such as the metal posts 98, between the heat dissipation plate 40 and the wiring substrate 20. This allows the semiconductor device 10 to be reduced in size as compared with when connecting members are included.

(13) The metal posts 98 are arranged in the first non-product region 82, which is located outside the first product regions 81, and the second non-product region 92, which is located outside the second product regions 91, and serve as connecting members connecting the first substrate 80 and the second substrate 90. Further, in a state in which the first substrate 80 and the second substrate 90 are connected by the metal posts 98, the encapsulation resin 50 is formed to encapsulate the semiconductor element 30 and fill the gap between the first substrate 80 and the second substrate 90 and the gap between the semiconductor element 30 and the second substrate 90.

With this structure, the encapsulation resin 50 is formed with the first substrate 80 and the second substrate 90 spaced apart over a given distance by the metal posts 98. Thus, subsequent to singulation, the wiring substrate 20 and the heat dissipation plate 40 will be spaced apart by the given distance in the semiconductor device 10. Further, subsequent to singulation, the semiconductor element 30 and the heat dissipation plate 40 will be spaced apart by a given distance in the semiconductor device 10. In addition, subsequent to singulation, the semiconductor device 10 will not include the metal posts 98. This allows the semiconductor device 10 to be reduced in size.

### MODIFIED EXAMPLES

The above embodiment may be modified as follows. The above embodiment and the following modifications may be combined as long as the combined modifications remain technically consistent with each other.

In the above embodiment, the upper surface 50T of the encapsulation resin 50 may be changed. For example, the sloped portion 52 may be omitted. In this case, the upper surface 50T includes only the flat portion 51.

In the above embodiment, the structure of the heat dissipation plate 40 may be changed.

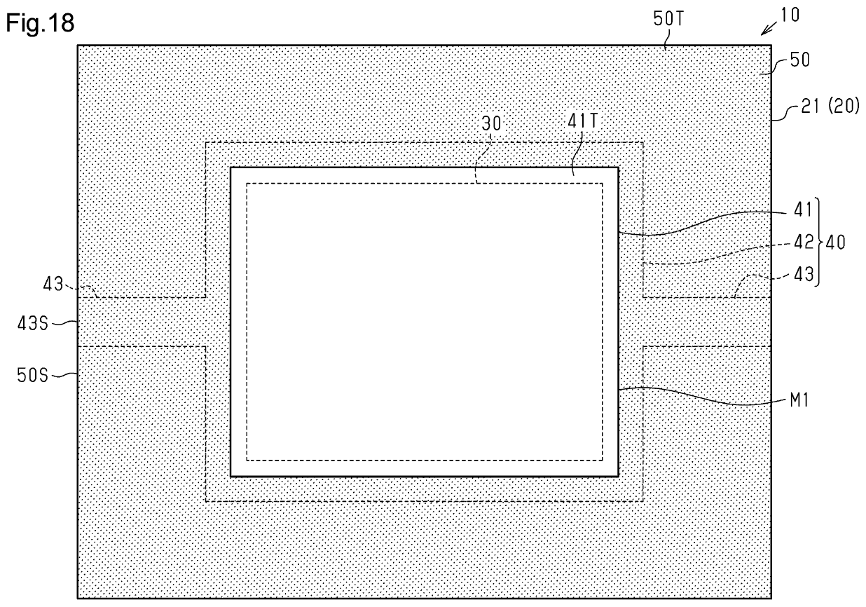

As illustrated in FIG. 18, for example, the lead 43 may be arranged on only two of the four sides of the rectangular contour of the main body 41. In this modified example, a single lead 43 is arranged on each of the two opposite sides in the left-right direction as viewed in FIG. 18.

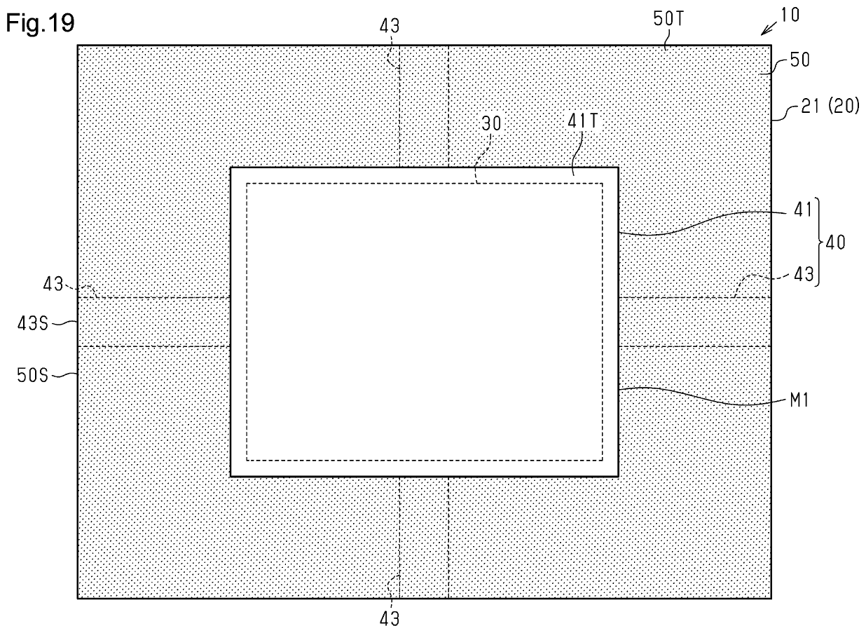

As illustrated in FIG. 19, for example, the projection 42 (refer to FIG. 2) may be omitted from the heat dissipation plate 40. In this case, the leads 43 project outward from the side surfaces of the main body 41. In this case, only the leads 43 of the heat dissipation plate 40 are embedded in the encapsulation resin 50.

In the above embodiment, the leads 43 may be omitted from the heat dissipation plate 40.

In the above embodiment, the planar shape of the main body 41 may be changed.

For example, the planar shape of the main body 41 may be a polygon other than a quadrangle, such as a circle or an ellipse.

In the above embodiment, only the encapsulation resin 50 supports the heat dissipation plate 40 above the wiring substrate 20. Instead, for example, the heat dissipation plate 40 may be mounted on the upper surface of the semiconductor element 30 with an adhesive or the like.

In the above embodiment, a surface-processed layer may be formed on the surface of the heat dissipation plate 40. The surface-processed layer may be, for example, an oxide film. The surface-processed layer may be, for example, a film of copper oxide including a hydroxide.

In the above embodiment, an outer plating layer may be formed on the surface of the main body 41 exposed from the encapsulation resin 50. Examples of the outer layer plating layer may include a Sn layer or a solder layer. The material of the solder layer may be, for example, an alloy including Pb, an alloy of Sn and Au, an alloy of Sn and Cu, an alloy of Sn and Ag, an alloy of Sn, Ag, and Cu, or the like.

In the above embodiment, the structure of the wiring substrate 20 may be changed. For example, the solder resist layer 25 may be omitted. For example, the wiring layer 24 may be changed in layout and quantity of portions. For example, the wiring layer 22 may be changed in layout and quantity of portions.

There is no limitation to the quantity of semiconductor elements 30 mounted on the wiring substrate 20. For example, two or more semiconductor elements 30 may be mounted on the wiring substrate 20.

In the above embodiment, the semiconductor element 30 may be mounted on the wiring substrate 20 in any manner. For example, the semiconductor element 30 may be mounted by flip-chip mounting, wire bonding, solder bonding, or a combination of these mounting methods.

In the above embodiment, an underfill resin may be arranged between the semiconductor element 30 and the substrate body 21.

In the above embodiment, the connecting members connecting the first substrate 80 and the second substrate 90 may be changed to connecting members other than the metal posts 98. For example, the connecting members may be changed to core solder balls. The core solder balls each include, for example, a spherical conductive core ball and a solder layer covering the conductive core ball.

In the above embodiment, the structure of the first substrate 80 may be changed. For example, the quantity and layout of the first connecting portions A1 may be changed. For example, a first connecting portion A1 may be arranged between two adjacent ones of the first product regions 81 in the left-right direction as viewed in FIG. 5.

In the above embodiment, the structure of the second substrate 90 may be changed. For example, the quantity and layout of the second connecting portions A2 may be changed. For example, a second connecting portion A2 may be arranged between two adjacent ones of the second product regions 91 in the left-right direction as viewed in FIG. 8.

### Clauses

This disclosure further encompasses the following embodiments.

1. A method for manufacturing a semiconductor device, the method including:
mounting a semiconductor element on a wiring substrate;
arranging a heat dissipation plate above the semiconductor element, the heat dissipation plate including a main body that overlaps the semiconductor element in plan view;
applying an adhesive film to an upper surface of the main body so that an upper portion of the main body is embedded in the adhesive film;
forming an encapsulation resin that encapsulates the semiconductor element and fills a gap between the wiring substrate and the heat dissipation plate; and
removing the adhesive film,
in which an upper surface of the encapsulation resin is located downward from the upper surface of the main body.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor device, comprising:
a wiring substrate;
a semiconductor element mounted on the wiring substrate;
a heat dissipation plate arranged above the semiconductor element; and
an encapsulation resin encapsulating the semiconductor element and filling a gap between the wiring substrate and the heat dissipation plate, wherein
the heat dissipation plate includes
a main body overlapping the semiconductor element in plan view, and
a lead projecting outward from the main body,
the lead is thinner than the main body,
the encapsulation resin includes a first outer side surface,
the lead includes a second outer side surface exposed from the first outer side surface of the encapsulation resin,
the encapsulation resin covers an upper surface of the lead and part of a side surface of the main body,
the encapsulation resin includes an upper surface located downward from an upper surface of the main body, and
the encapsulation resin exposes an entirety of the upper surface of the main body and an upper portion of the side surface of the main body.

2. The semiconductor device according to claim 1, further comprising
a step formed between the upper surface of the encapsulation resin and the upper surface of the main body, the step extending along a contour of the upper surface of the main body in plan view.

3. The semiconductor device according to claim 1, wherein
the upper surface of the encapsulation resin includes a sloped portion contacting the side surface of the main body, and
the sloped portion is sloped downward as the sloped portion extends away from the side surface of the main body.

4. The semiconductor device according to claim 3, wherein the sloped portion is a curved surface curved in an arcuate manner.

5. The semiconductor device according to claim 3, wherein the upper surface of the encapsulation resin includes a flat portion continuous with the sloped portion.

6. The semiconductor device according to claim 1, wherein the encapsulation resin covers a lower surface of the lead and a side surface of the lead except for the second outer side surface.

7. The semiconductor device according to claim 1, wherein the encapsulation resin fills a gap between the wiring substrate and the semiconductor element.

8. The semiconductor device according to claim 1, wherein
the heat dissipation plate includes a projection projecting outward from the side surface of the main body,
the projection surrounds the main body in plan view,
the projection is thinner than the main body,
the lead projects outward from a side surface of the projection, and
the encapsulation resin covers an upper surface of the projection and a side surface of the projection.

9. The semiconductor device according to claim 1, wherein
the main body has a rectangular planar shape, and
the lead is arranged on at least two of four sides of the main body in plan view.

10. The semiconductor device according to claim 1, wherein
the encapsulation resin fills a gap between the semiconductor element and the heat dissipation plate, and
the heat dissipation plate is supported above the wiring substrate by only the encapsulation resin.
